(19) United States
(12) Patent Application Publication
(10) Pub. No.: US 2011/0227226 A1
(43) Pub. Date: Sep. 22, 2011

(54) MULTI-CHIP STACK STRUCTURE HAVING THROUGH SILICON VIA

(75) Inventors: Chiang-Cheng Chiang, Taichung (TW); Chien-Ping Huang, Taichung (TW); Chin-Huang Chang, Taichung (TW); Chi-Hsin Chiu, Taichung (TW); Jung-Pin Huang, Taichung (TW)

(73) Assignee: SILICONWARE PRECISION INDUSTRIES CO., LTD., Taichung (TW)

(21) Appl. No.: 13/151,823

(22) Filed: Jun. 2, 2011

Related U.S. Application Data
(62) Division of application No. 12/220,995, filed on Jul. 30, 2008.

(30) Foreign Application Priority Data
Jul. 31, 2007 (TW) 096127941

(51) Int. Cl. H01L 23/48

(52) U.S. Cl. 257/751; 257/E23.011

(57) ABSTRACT

The invention discloses a multi-chip stack structure having through silicon via and a method for fabricating the same. The method includes: providing a wafer having a plurality of first chips; forming a plurality of holes on a first surface of each of the first chips and forming metal posts and solder pads corresponding to the holes so as to form a through silicon via (TSV) structure; forming at least one groove on a second surface of each of the first chips to expose the metal posts of the TSV structure so as to allow at least one second chip to be stacked on the first chip, received in the groove and electrically connected to the metal posts exposed from the groove; filling the groove with an insulating material for encapsulating the second chip; mounting conductive elements on the solder pads of the first surface of each of the first chips and singulating the wafer; and mounting and electrically connecting the stacked first and second chips to a chip carrier via the conductive elements. The wafer, which is not totally thinned but includes a plurality of first chips, severs a carrying purpose during the fabrication process and thereby solves problems, namely a complicated process, high cost, and adhesive layer contamination, facing the prior art that entails repeated use of a carrier board and an adhesive layer for vertically stacking a plurality of chips and mounting the stacked chips on a chip carrier.

### BACKGROUND OF THE INVENTION

1. Field of the Invention

The present invention relates generally to semiconductor devices and method for fabricating the same, and more particularly to a multi-chip stack structure having through silicon via (TSV) and a method for fabricating the same.

2. Description of Related Art

A conventional multi-chip module (MCM) semiconductor package comprises two or more chips, which are disposed to a common substrate, horizontally spaced from each other, and electrically connected to the substrate by wire bonding. However, to prevent miscontact between conductive wires of the chips, a certain interval is required between the chips. Accordingly, a large die attachment area is required on the substrate for attachment of a large number of chips, thus increasing the use area of the substrate and the fabrication cost.

U.S. Pat. No. 6,538,331 discloses a chip stack structure with a first chip and a second chip stack disposed on a substrate, wherein the second chip is stacked on the first chip and offsets a certain distance from the first chip so as to facilitate the wire bonding process of the first and second chips.

The stack structure saves substrate space compared with the horizontally spaced structure. However, since the chips of the stack structure are electrically connected to the substrate through wire bonding, quality of electrical connections between the chips and the substrate are adversely affected by length of the bonding wires. Meanwhile, since an offset distance is required between the stacked chips and space for bonding wires is quite limited, the number of chips that can be received by the package is also limited.

Accordingly, referring to FIGS. 1A to 1G, U.S. Pat. No. 5,270,261 and No. 5,202,754 disclose a method for vertically stacking and electrically connecting a plurality of semiconductor chips using a TSV (Through Silicon Via) technique.

As shown in FIG. 1A, a first wafer 11a having a plurality of first chips 11 is provided. The first wafer 11a has a first surface 111 and a second surface 112 opposed to the first surface 111. A plurality of holes 110 is formed on the first surface 111 and metal posts 13 are formed in the holes 110 so as to form a TSV structure. Solder pads 131 are formed on ends of the metal posts 13 exposed from the first surface 111. The first surface 111 of the first wafer 11a is adhered to a carrier board 151 such as glass through an adhesive layer 141, wherein the carrier board 151 provides required supporting strength for the fabrication process. As shown in FIG. 1B, the second surface 112 of the first wafer 11a is thinned through a grinding process so as to expose the metal posts 13. As shown in FIG. 1C, solder pads 132 are formed on the metal posts 13 exposed from the second surface 112 such that a second wafer 12a having a TSV structure and a plurality of second chips 12 is vertically mounted and electrically connected to the second surface 112 of the first wafer 11a through the metal posts 16. Then, as shown in FIG. 1D, the second wafer 12a is thinned through a grinding process so as to expose the metal posts 16 thereof and solder pads 136 are formed on the exposed metal posts 16. As shown in FIG. 1E, the first and second wafers 12a are adhered to another carrier board 152 through an adhesive layer 142, and the carrier board 151 and the adhesive layer 141 are removed so as to expose the first surface 111 of the first wafer 11a. As shown in FIG. 1F, a plurality of solder balls 17 is mounted on the solder pads 131 of the first surface 111 of the first wafer 11a such that the first and second chips 11, 12 can be electrically connected to an external device. As shown in FIG. 1 the first and second wafers 11a, 12a are singulated so as to form a plurality of vertically stacked first and second chips 11, 12. The stacked structure of the first and second chips is then electrically connected to a substrate 18 through the solder balls 17, thereby forming a MCM semiconductor package.

However, the above-described fabrication process requires a plurality of carrier boards 151, 152, to which the first and second wafers 11a, 12a are repeatedly attached, which not only increase the fabrication cost but also complicates the fabrication process. Further, in the case the adhesive layers 141, 142 are made of a polymer material such as an epoxy resin, the solder pads 131, 136 can be contaminated by the adhesive layers during the sputtering process of the solder pads and subsequent wet etching process of the adhesive layers.

Therefore, there is an urgent need to develop a multi-chip stack structure and a method for fabricating the same which eliminate the need of carrier boards and adhesive layers as in the prior art so as to simplify the fabrication process and reduce the fabrication cost and further prevent problem of contamination induced by adhesive layers made of a polymer material.

### SUMMARY OF THE INVENTION

Accordingly, an object of the present invention is to provide a multi-chip stack structure having TSV and a method for fabricating the same, which eliminates the need of carrier boards and adhesive layers in the fabrication process.

Another object of the present invention is to provide a multi-chip stack structure having TSV and a method for fabricating the same, which has simplified fabrication process and low cost.

A further object of the present invention is to provide a multi-chip stack structure having TSV and a method for fabricating the same, which avoids the use of adhesive layers made of polymer material so as to overcome the conventional contamination problem.

In order to attain the above and other objects, the present invention discloses a method for fabricating a multi-chip stack structure having TSV, which comprises: providing a wafer having a plurality of first chips, wherein the wafer and the first chips each have a first surface and a second surface opposed to the first surface, a plurality of holes is formed on the first surface of each of the first chips and metal posts and solder pads are formed corresponding to the holes so as to form a TSV structure; forming at least one groove on the second surface of each of the first chips with the metal posts of the TSV structure exposed from the bottom of the groove; and staking at least a second chip on each of the first chips and electrically connecting the second chip to the metal posts of the corresponding first chip exposed from the groove.

The method further comprises: filling an insulating material in the grooves of the first chips for encapsulating the second chips; flattening the insulating material so as to make the insulating material be flush with the second surfaces of the first chips; mounting conductive elements on the solder pads on the first surfaces of the first chips; singulating the wafer to separate the first chips from each other; and mounting and electrically connecting a separated first chip with the corresponding second chip stacked thereon to a chip carrier through the conductive elements.

Further, the second chip has TSV formed therein such that a third chip can be stacked on and electrically connected thereto. Moreover, a fourth chip can be stacked on the solder pads on the first surface of the first chip. Therefore, the number of the chips is increased and the electrical performance of the whole structure is strengthened.

Through the above-described fabrication method, the present invention further discloses a multi-chip stack structure having through silicon via (TSV), which comprises: a first chip having a first surface and a second surface opposed to the first surface, wherein a plurality of holes is formed on the first surface, metal posts and solder pads are formed corresponding to the holes so as to form a TSV structure, at least one groove is formed on the second surface to expose the metal posts; and at least a second chip stacked on the first chip and electrically connected to the metal posts exposed from the groove.

The multi-chip stack structure further comprises: an insulating material filled in the groove of the first chip and encapsulating the second chip; conductive elements mounted on the solder pads on the first surface of the first chip; and a chip carrier to which the stacked first and second chips are mounted and electrically connected through the conductive elements.

According to another embodiment, the structure further comprises a third chip stacked on the second chip, and the second chip has TSV formed therein for electrically connecting the third chip. According to another embodiment, the structure further comprises a fourth chip mounted on and electrically connected to the solder pads on the first surface of the first chip.

Therefore, the present invention mainly comprises forming a plurality of holes on the first surface of the wafer having a plurality of first chips and forming metal posts and solder pads corresponding to the holes so as to form a TSV structure; forming at least one groove on the second surface of each of the first chips to expose the metal posts of the TSV structure such that at least a second chip can be stacked on the first chip and received in the groove and electrically connected to the metal posts exposed from the groove, thereby forming a vertical stack structure of the first chip and the second chip; subsequently filling a insulating material in the grooves to encapsulate the second chips and flattening the insulating material so as to make the insulating material be flush with the second surfaces of the first chips; thereafter mounting conductive elements on the solder pads on the first surfaces of the first chips and singulating the wafer so as to separate the first chips from each other; then mounting and electrically connecting a separated first chip stacked with the corresponding second chip to a chip carrier. Therefore, the present invention uses the wafer that is not totally thinned as a carrier structure in the fabrication process so as to prevent repeated use of the carrier boards and adhesive layers as in the prior art for vertically stacking a plurality of chips, thereby simplifying the fabrication process, saving the fabrication cost and avoiding the problem of contamination.

### BRIEF DESCRIPTION OF DRAWINGS

FIGS. 1A to 1G are diagrams showing a method for vertically stacking a plurality of semiconductor chips using TSV technique disclosed by U.S. Pat. No. 5,270,261 and No. 5,202,754;

FIGS. 2A to 2F are diagrams showing a multi-chip stack structure and a method for fabricating the same according to a first embodiment of the present invention;

FIGS. 2D′ and 2E′ are diagrams showing another embodiments of structures of FIGS. 2D and 2E;

FIGS. 3A to 3D are diagrams showing a multi-chip stack structure and a method for fabricating the same according to a second embodiment of the present invention; and

FIG. 4 is a diagram showing a multi-chip stack structure and a method for fabricating the same according to a third embodiment of the present invention.

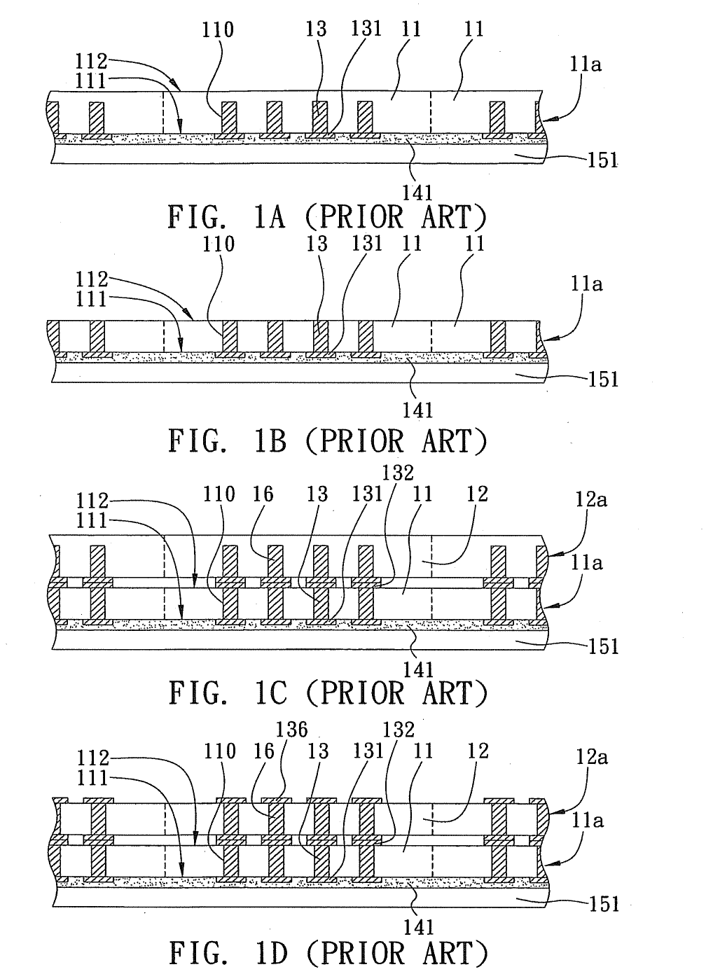

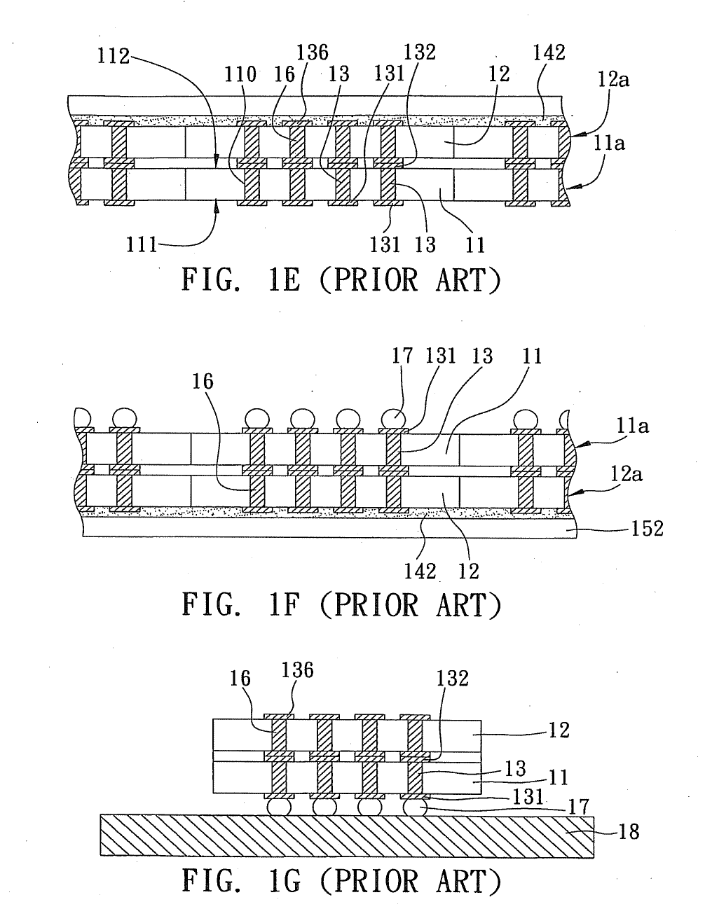

### DETAILED DESCRIPTION OF PREFERRED EMBODIMENTS

The following illustrative embodiments are provided to illustrate the disclosure of the present invention, these and other advantages and effects can be apparent to those skilled in the art after reading the disclosure of this specification.

### First Embodiment

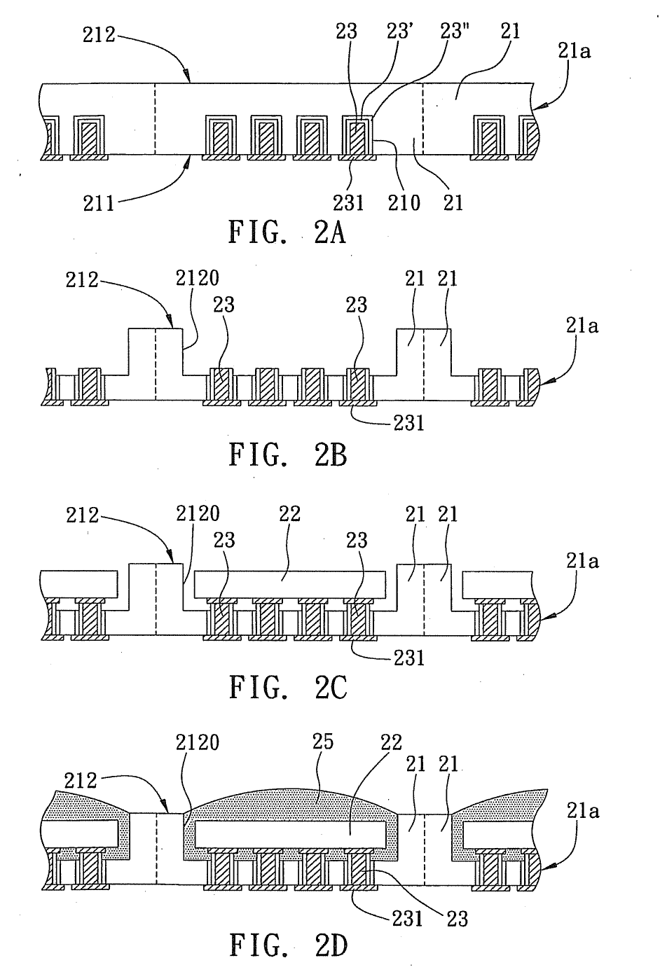

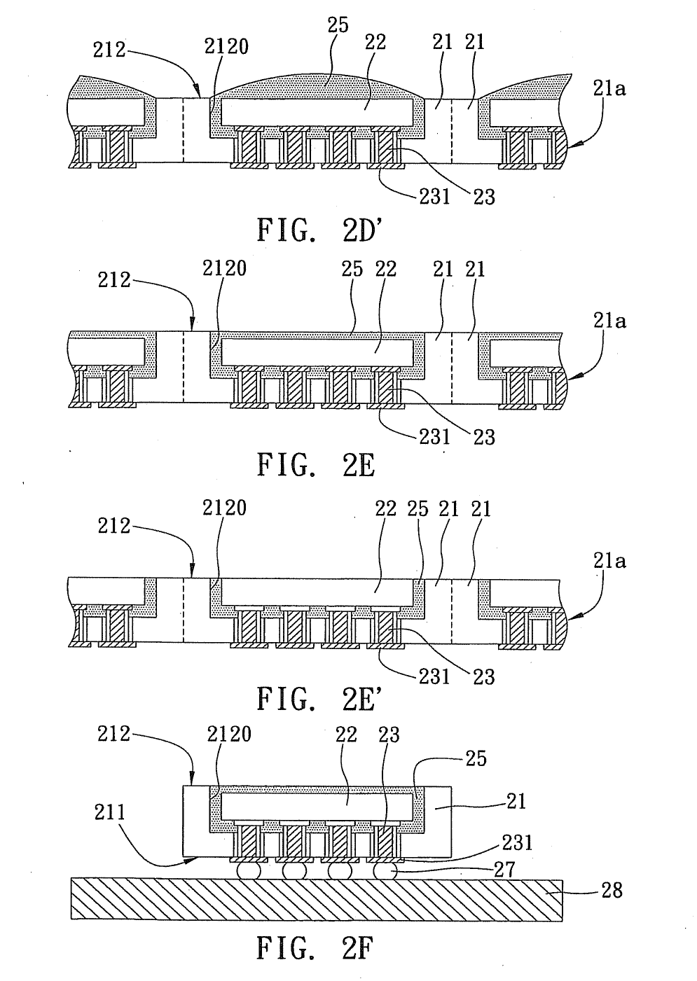

FIGS. 2A to 2F are diagrams showing a multi-chip stack structure having through silicon via (TSV) and a method for fabricating the same according to a first embodiment of the present invention.

As shown in FIG. 2A, a wafer 21a comprising a plurality of first chips 21 is provided. The wafer 21a and the first chips 21 each have a first surface 211 and a second surface 212 opposed to the first surface 211. A plurality of holes 210 is formed on the first surface 211 of each of the first chips 21, and metal posts 23 and solder pads 231 are formed corresponding to the holes 210 so as to form a TSV structure.

An insulating layer 23″ made of such as silicon dioxide or silicon nitride is disposed between the holes 210 and the metal posts 23, and a barrier layer 23′ made of such as nickel is disposed between the insulating layer 23″ and the metal posts 23. The metal posts 23 are made of such as copper, gold or aluminum.

As shown in FIG. 2B, at least a groove 2120 is formed on the second surface 212 of each of the first chips 21 by DRIB (Deep Reactive Ion Etching), and the metal posts 23 are exposed from the bottom of the groove 2120, wherein the metal posts 23 can protrude from the bottom of the groove 2120.

As shown in FIG. 2C, at least a second chip 22 is stacked on each of the first chips 21, received in the groove 2120 and electrically connected to the metal posts 23 exposed from the groove 2120.

As shown in FIGS. 2D and 2E, a insulating material 25 such as an encapsulant is filled in the grooves 2120 to encapsulate the second chips 22. Thereafter, the insulating material 25 is flattened through a grinding process such that the outer surface of the insulating material 25 is flush with the second surfaces 212 of the first chips 21.

The mounting height of the second chips 22 can be lower than the second surfaces 212 of the first chips 21 such that the insulating material 25 after the grinding process still encapsulates the second chips 22, as shown in FIG. 2E. Alternatively, the mounting height of the second chips 22 can be flush with or slightly higher than the second surfaces 212 of the first chips 21 such that the second chips 22 can be exposed from the insulating material 25 after the grinding process, as shown in FIGS. 2D′ and 2E′.

As shown in FIG. 2F, conductive elements 27 are mounted on the solder pads 231 of the first surfaces 211 of the first chips 21 and the wafer 21a is singulated so as to separate the first chips from each other. And a pick-up process is performed so as to mount the stacked second chip 22 and first chip 21 to a chip carrier 28 through the conductive elements 27.

Through the above-described method, the present invention further discloses a multi-chip stack structure having TSV, which comprises: a first chip 21 having a first surface 211 and a second surface 212 opposed to the first surface 211, wherein a plurality of holes 210 is formed on the first surface 211, and metal posts 23 and solder pads 231 are formed corresponding to the holes 210 so as to form a TSV structure, at least one groove 2120 is formed on the second surface 212 to expose the metal posts 23 of the TSV structure; and at least a second chip 22 stacked on the first chips 21 and electrically connected to the metal posts 23 exposed from the groove 2120 of the TSV structure.

The multi-chip stack structure having TSV further comprises: a insulating material 25 filled in the groove 2120 of the first chip 21 and encapsulating the second chip 22; conductive elements 27 mounted on the solder pads 231 of the first surface 211 of the first, chip 21; and a chip carrier 28 to which the second chip 22 and the first chip 21 are mounted and electrically connected through the conductive elements 27.

Therefore, the present invention mainly comprises forming a plurality of holes on the first surface of the wafer having a plurality of first chips and forming metal posts and solder pads corresponding to the holes so as to form a TSV structure; forming at least one groove on the second surface of each of the first chips to expose the metal posts of the TSV structure such that at least a second chip can be stacked on the first chip and received in the groove and electrically connected to the metal posts exposed from the groove, thereby forming a vertical stack structure of the first chip and the second chip; subsequently filling a insulating material in the grooves to encapsulate the second chips and flattening the insulating material so as to make the insulating material be flush with the second surfaces of the first chips; thereafter mounting conductive elements on the solder pads of the first surfaces of the first chips and singulating the wafer so as to separate the first chips from each other; then mounting and electrically connecting a separated first chip stacked with the corresponding second chip to a chip carrier. Therefore, the present invention uses the wafer that is not totally thinned as a carrier structure in the fabrication process so as to prevent repeated use of the carrier boards and adhesive layers as in the prior art for vertically stacking a plurality of chips, thereby simplifying the fabrication process, saving the fabrication cost and avoiding the problem of contamination.

### Second Embodiment

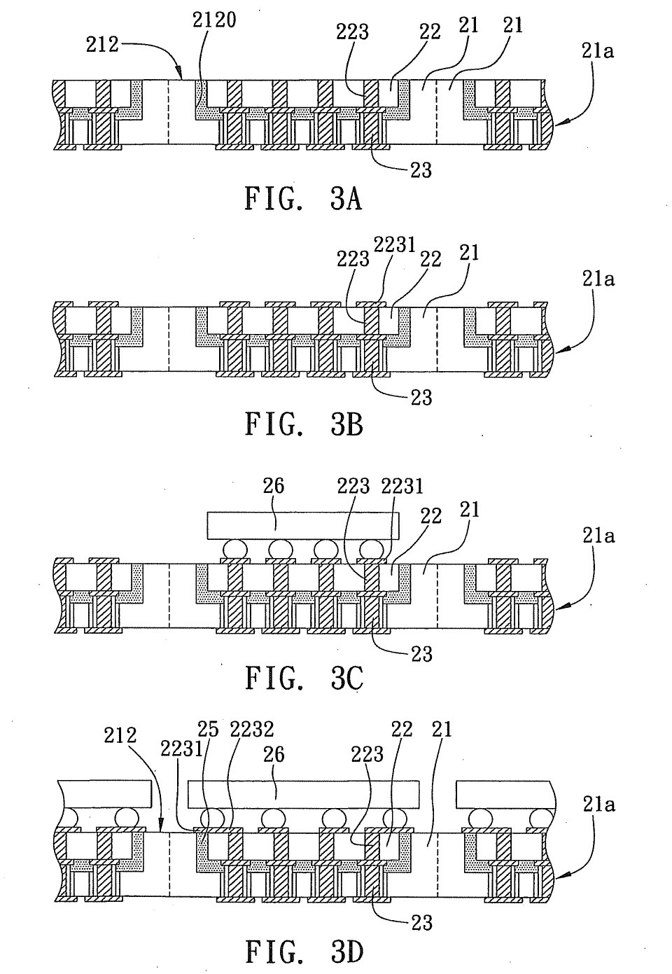

FIGS. 3A to 3D are diagrams showing a multi-chip stack structure having TSV and a method for fabricating the same according to a second embodiment of the present invention. The elements of the present embodiment that are same as or similar to those of the above-described embodiment are denoted by the same reference numerals.

The present embodiment is mostly similar to the first embodiment, a main difference therebetween is TSV is formed in the second chip such that a third chip can be vertically stacked on the second chip and electrically connected to the second chip, thereby enhancing electrical performance of the whole structure.

As shown in FIG. 3A, at least a second chip 22 is disposed in the groove 2120 of the second surface 212 of the first chip 21 and electrically connected to the metal posts 23 of the first chip 21 exposed from the groove 2120, wherein the second chip 22 has metal posts 223 formed therein so as to form a TSV structure. An insulating material 25 is filled in the groove 2120 and flattened through a grinding process to expose the metal posts 223 of the second chip 22 from the insulating material 25.

As shown in FIG. 3B, solder pads 2231 are formed on the metal posts 223 of the second chip 22 by such as sputtering.

As shown in FIG. 3C, the third chip 26 is mounted on the second chip 22 and electrically connected to the solder pads 2231 of the second chip 22.

Further, referring to FIG. 3D, a re-distribution layer (RDL) 2232 is alternatively formed on the second chip 22 and the insulating material 25 as well as the second surface 212 of the first chip 21 and electrically connected to the metal posts 223 of the second chip 22, and solder pads 2231 are formed on ends of the RDL 2232 for electrically connecting the third chip 26 to the solder pads 2231.

Subsequently, conductive elements can be mounted on the first surface of the first chip and the wafer is singulated to separate the first chips from each other. Thereafter, the stacked first, second and third chips can be mounted on and electrically connected to a chip carrier through the conductive elements.

### Third Embodiment

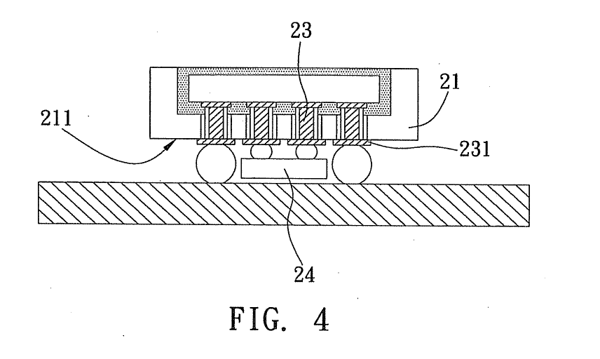

FIG. 4 is a diagram showing a multi-chip stack structure having TSV and a method for fabricating the same according to a third embodiment of the present invention. For simplification, the elements same as or similar to the above-described embodiments are denoted by the same reference numerals.

The present embodiment is mostly similar to the above-described embodiments, a main difference of the present embodiment from the above-described embodiments is at least a fourth chip 24 is further disposed on the first surface 211 of the first chip and electrically connected to the solder pads 231 on the first surface 211 of the first chip 12, thereby enhancing electrical performance of the whole structure.

The above-described descriptions of the detailed embodiments are only to illustrate the preferred implementation according to the present invention, and it is not to limit the scope of the present invention. All modifications and variations completed by those with ordinary skill in the art should fall within the scope of present invention defined by the appended claims.

1-27. (canceled)

28. A multi-chip stack structure having TSV (Through Silicon Via), comprising:
a first chip having a first surface and a second surface opposed to the first surface, wherein a plurality of holes is formed on the first surface, metal posts and solder pads are formed corresponding to the holes so as to form a TSV structure, and at least one groove is formed on the second surface to expose the metal posts;
at least a second chip having TSV, the second chip being stacked on the first chip and electrically connected to the metal posts of the TSV structure of the first chip exposed from the groove;
an insulating material formed in the groove, the metal posts of the TSV structure of the second chip being exposed from the insulating material;
solder pads formed on the second chip and electrically connected to the metal posts of the TSV structure of the second chip exposed from the insulating material; and
a third chip mounted on the second chip and electrically connected to the solder pads of the second chip.

29. The structure of claim 28, further comprising an insulating layer disposed between the holes and the metal posts of the first chip, and a barrier layer disposed between the insulating layer and the metal posts of the first chip.

30. The structure of claim 29, wherein the insulating layer is made of one of silicon dioxide and silicon nitride, the barrier layer is made of nickel, and the metal posts are made of one the group consisting of copper, gold and aluminum.

31. The structure of claim 28, further comprising conductive elements mounted on the solder pads on the first surface of the first chip.

32. The structure of claim 31, further comprising a chip carrier, the stacked first, second and third chips being mounted and electrically connected to the chip carrier through the conductive elements.

33. The structure of claim 28, wherein the solder pads of the second chip are directly formed on the metal posts of the second chip.

34. The structure of claim 28, wherein the solder pads of the second chip are electrically connected to the metal posts of the second chip through a re-distribution layer (RDL).
